(19) United States
(12) Patent Application Publication
(10) Pub. No.: US 2026/0305257 A1
(43) Pub. Date: Oct. 1, 2026

(54) MOVABLE RACK SYSTEM AND OPERATING METHOD OF THE SAME

(71) Applicants: TSMC China Company Limited, Shanghai (CN); TAIWAN SEMICONDUCTOR MANUFACTURING COMPANY, LTD., Hsinchu (TW)

(72) Inventors: Xiao JIN, Shanghai City (CN); Rong ZHU, Shanghai City (CN); Chen CHEN, Shanghai City (CN); Wen-Jing HUANG, Shanghai City (CN)

(73) Assignees: TSMC China Company Limited, Shanghai (CN); TAIWAN SEMICONDUCTOR MANUFACTURING COMPANY, LTD., Hsinchu (TW)

(21) Appl. No.: 19/192,919

(22) Filed: Apr. 29, 2025

(30) Foreign Application Priority Data
Mar. 28, 2025 (CN) 202520578831.0

(51) Int. Cl. H01L 21/687; H01L 21/68

(52) U.S. Cl. CPC H10P 72/7618; H10P 72/50; H10P 72/7608; H10P 72/7621

(57) ABSTRACT

A method includes releasing a fixing device to allow a movement of a rack using a movable track of a linear track system at a first position; moving the rack using the movable track from the first position to a second position; engaging the fixing device to secure the rack in place at the second position; releasing the fixing device to allow the rack to return to the first position using the movable track; engaging the fixing device to lock the rack at the first position.

### PRIORITY CLAIM AND CROSS-REFERENCE

This application claims priority to CN Application Serial Number 202520578831.0, filed Mar. 28, 2025, which is herein incorporated by reference.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a fabrication facility in accordance with some embodiments of the present disclosure.

FIG. 2 illustrates a semiconductor fabrication plant including trolleys, production tools, stockers, and a wafer transport channel in accordance with some embodiments of the present disclosure.

FIGS. 3 to 5 illustrate schematic views of various stages of a method for moving rack by a linear track system in accordance with some embodiments of the present disclosure.

FIGS. 6 to 8C illustrate schematic views of a linear track system in accordance with some embodiments of the present disclosure.

FIGS. 9A and 9B illustrate schematic views of various stages of a method for moving rack by a linear track system in accordance with some embodiments of the present disclosure.

FIG. 10 is a flowchart of a method of using a linear track system to move a rack in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

A rack (or shelves) used by auto robot in semiconductor manufacturing often need to be moved to create space, but their repositioning presents a challenge. Specifically, after a rack is moved and then returned, it requires extensive recalibration to ensure proper alignment, which can take, such as more than 12 hours. This recalibration process is both time-consuming and often unreliable, with uncertainties regarding the stability and accuracy of the returned position, leading to further delays and verification procedures.

Therefore, the present disclosure in various embodiments provides a mechanical structure that can allow the rack to be moved along a track and return precisely to their original position. This mechanical structure that can include a fixing device (e.g., quick-clamp device) and a linear track system. The fixing device can fix the rack securely in place both before and after movement, ensuring that the rack remains stable and is accurately repositioned. The rack can be mounted on a track that facilitates smooth horizontal movement. This disclosure also can incorporate a cable drag chain to manage cables during movement, reducing the risk of tangling and ensuring safe, orderly operation. Therefore, this disclosure can allow for movement of the rack, with the fixing device being released to allow for movement along the track. After reaching the desired position, the fixing device can be re-engaged to secure the rack in its desired position without the need for extensive recalibration.

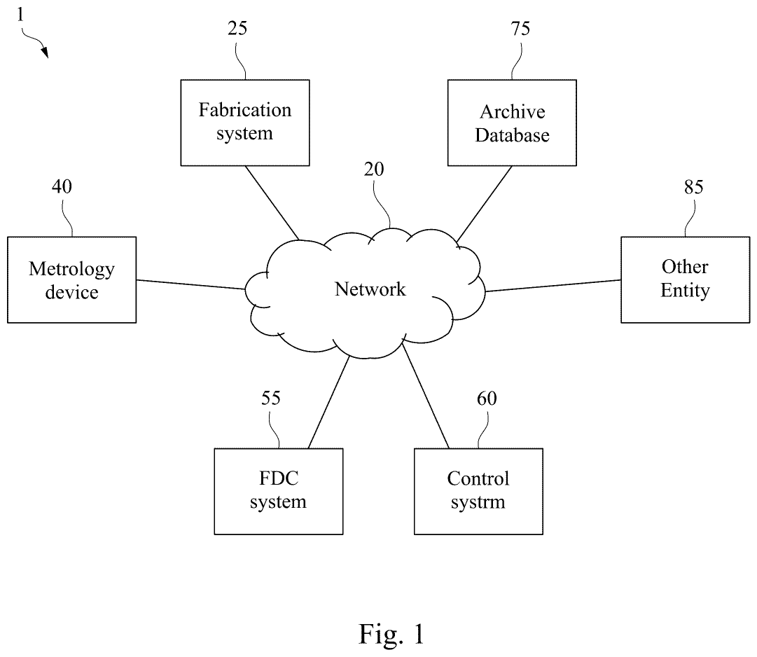

Reference is made to FIG. 1. FIG. 1 is a block diagram of a fabrication facility in accordance with some embodiments of the present disclosure. The fabrication facility 1 implements integrated circuit manufacturing processes to fabricate integrated circuit devices. For example, the fabrication facility 1 may implement semiconductor manufacturing processes that fabricate semiconductor wafers. It should be noted that, in FIG. 1, the fabrication facility 1 has been simplified for the sake of clarity to better understand the concepts of the present disclosure. Additional features can be added in the fabrication facility 1, and some of the features described below can be replaced or eliminated in other embodiments of the fabrication facility 1. The fabrication facility 1 may include more than one of each of the entities. In some embodiments, and may further include other entities not illustrated in the depicted embodiment. In some embodiments, the fabrication facility 1 can include a network 20 that enables various entities (a fabrication system 25, a metrology device 40, a fault detection and classification (FDC) system 55, a control system 60, an archive data base 75, and another entity 85) to communicate with one another. The network 20 may be a single network or a variety of different networks, such as an intranet, the Internet, another network, or a combination thereof. The network 20 may include wired communication channels, wireless communication channels, or a combination thereof.

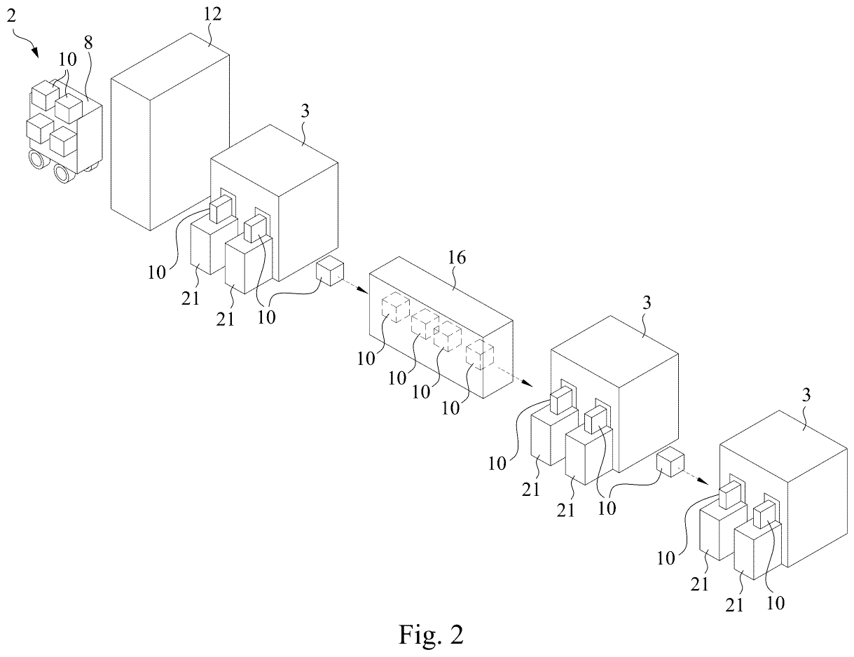

Reference is made to FIG. 2. FIG. 2 illustrates an exemplary manufacturing line 2 implementing integrated circuit manufacturing processes to fabricate integrated circuit devices. For example, the manufacturing line 2 may implement semiconductor manufacturing processes that fabricate semiconductor wafers. It should be noted that, in FIG. 2, the manufacturing line 2 has been simplified for the sake of clarity to better understand the concepts of the present disclosure. As shown in FIG. 2, the manufacturing line 2 may include production tools 3. The manufacturing line may further include a trolley 8, a stocker 12, and a wafer transport channel 16. The trolley 8 and wafer transport channel 16 can be used to transport wafer carriers 10. In some embodiments, the wafer carriers 10 can be made of quartz and/or polypropylene (PP). In some embodiments, the wafer carrier 104 can be interchangeably referred to as wafer holders, cassettes, or front opening unified pods (FOUPs). In some manufacturing processes, wafers need to go through one or more of the above-discussed tools. For example, the wafer carriers 10 can be configured to accommodate wafers. The wafer carriers 10 may be transported by the trolley 8 into the stocker 12, which has wafer storage for storing wafers. The wafer carriers 10 may also be transported to the load ports 21, which load wafers into and take wafers out of the production tools 3. The production tools 3 can perform manufacturing steps to the wafers. The transportation between the production tools 3 may be performed using the trolleys 8 or the automatic wafer transport channel 16. In some embodiments, the tool can be interchangeably referred to as an apparatus.

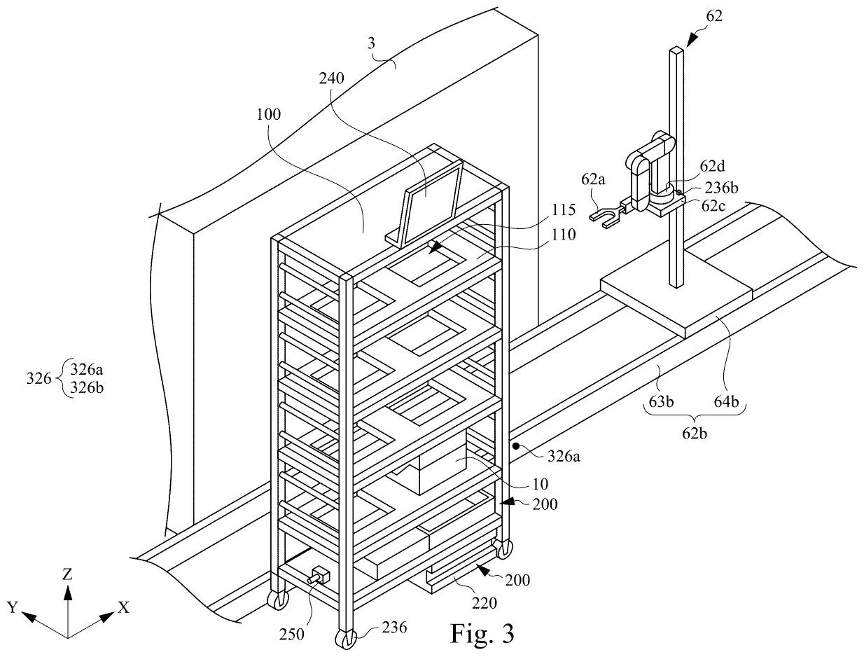

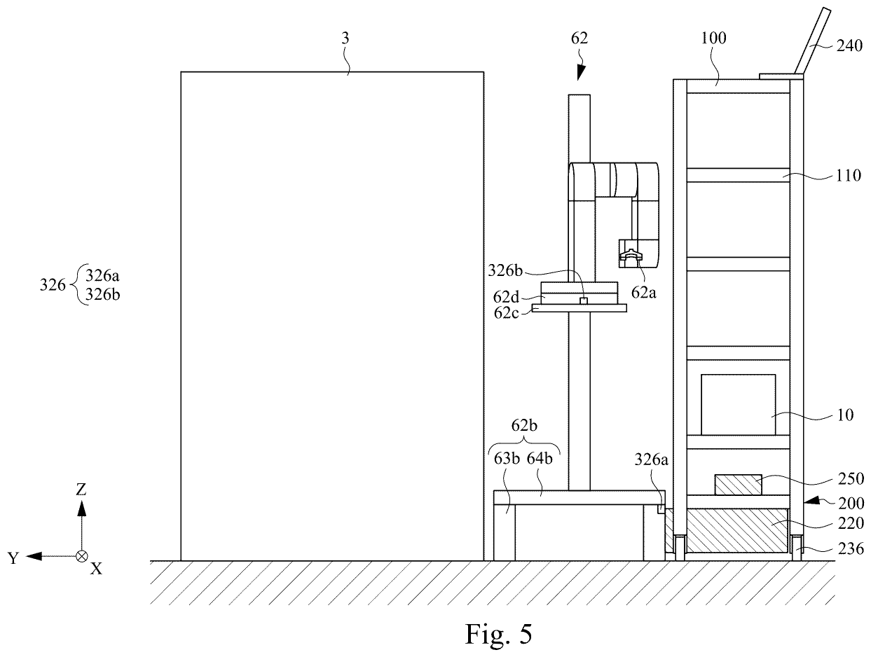

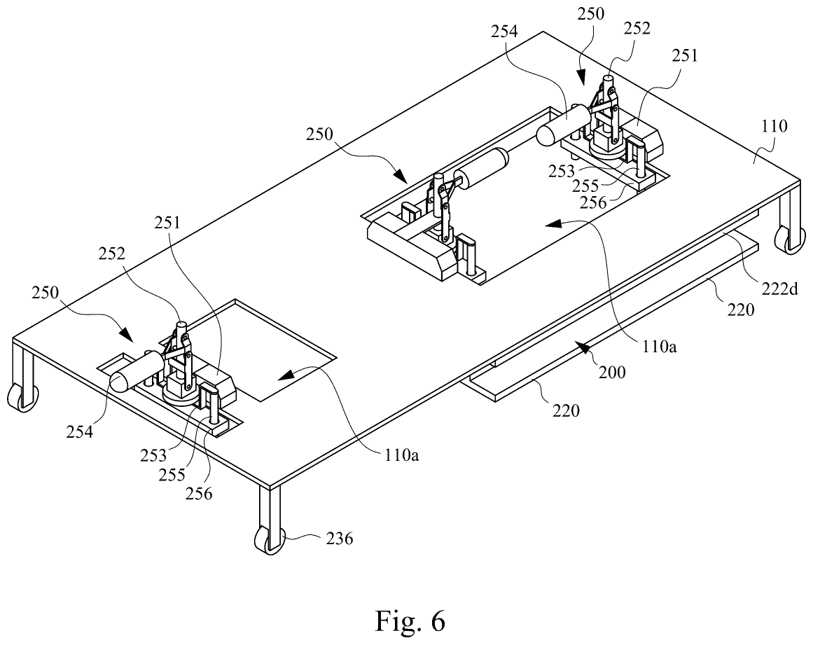

Reference is made to FIGS. 3 to 8C. FIGS. 3 and 5 illustrate schematic views of various stages of a method for moving a rack 100 by a linear track system 200 in accordance with some embodiments of the present disclosure. In some embodiments, the rack 100 can be interchangeably referred to as a wafer carrier rack, and the linear track system 200 can be interchangeably referred to as a linear guidance system. FIGS. 6 to 8C illustrate schematic views of the linear track system 200 and fixing devices 250 in accordance with some embodiments of the present disclosure. In some embodiments, the fixing device 250 can be interchangeably referred to as a securing mechanism.

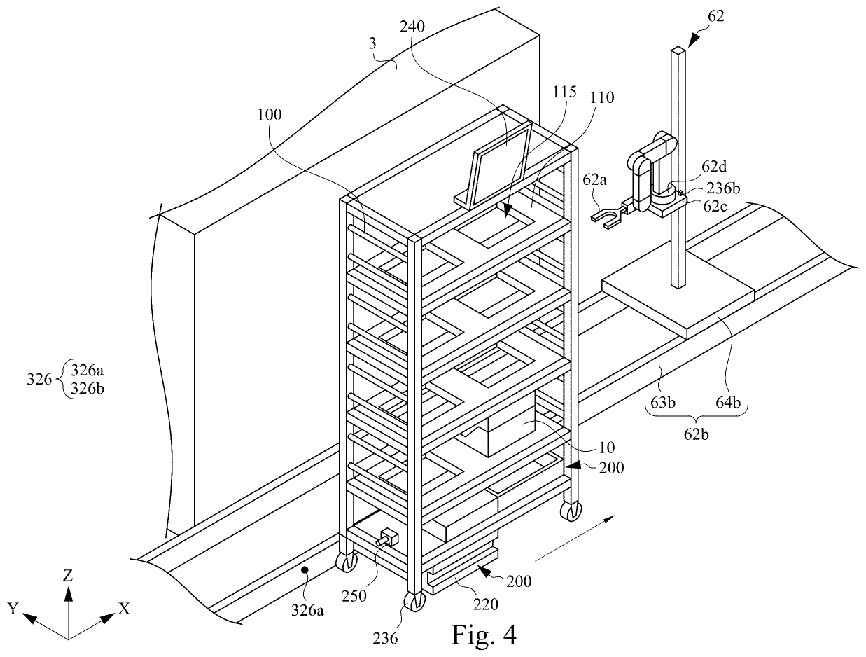

In some embodiments, after the wafers complete the process in the production tool 3, the wafers can be moved to the wafer carrier 10 on the load port 21 (see FIG. 2). Subsequently, the wafers can be moved to the rack 100 using the wafer carrier 10 (see FIGS. 3 and 4) to facilitate the next stage of processing. The wafer carrier 10 may include plural slots/fixtures for holding plural wafers and spacing the wafers from each other. In some embodiments, the wafer carrier 10 assumes an angle with respect to the horizontal so that wafers can be induced to rest on their respective rear surfaces and the front or upper surfaces of the wafers are not in contact with anything.

The rack 100 can be positioned on one side of the production tool 3. Between the rack 100 and the production tool 3, a transfer module 62 may be installed to facilitate the movement of wafer carriers 10. The transfer module 62 can allow the wafer carriers 10 to be transported smoothly along a path between the rack 100 and the production tool 3, ensuring efficient and precise handling during the semiconductor manufacturing process.

Specifically, the transfer module 62, integrated within the production tool 3 and the rack 100 can include components that coordinate to manipulate and transport wafer carriers 10 with high precision across various dimensions and orientations. In some embodiments, the transfer module 62 can include a wafer container gripper 62a for securely holding the wafer carrier 10 during transit. The wafer container gripper 62a can be in various shapes and sizes to accommodate different container specifications, ensuring a firm and safe grip without damaging the contents. In some embodiments, the transfer module 62 can further include a linear actuator 62b including a horizontal slide rail 63b and a movable carrier 64b, the linear actuator can facilitate smooth horizontal movements along the rail, and the actuator can power these movements, allowing for precise positioning along the X-axis within the facility. In some embodiments, the horizontal slide rail 63b can be interchangeably referred to as a horizontal slide track. In some embodiments, the transfer module 62 can further include a lifter 62c equipped with a vertical slide rail and a movable carrier operated by an actuator, the lifter 62c can enable vertical movement, allowing the transfer module 62 to adjust the elevation of the wafer carriers 10, accommodating different tiers within the rack 100 or aligning with equipment at various heights. In some embodiments, the transfer module 62 can further include a rotor 62d to control the rotational movements of the transfer module 62, enhancing the ability of the wafer container gripper 62a to adjust orientations.

Therefore, the wafer container gripper 62a can move seamlessly in three directions (e.g., horizontally along the X and Y axes and vertically along the Z axis). This multidirectional capability can be used for navigating the layout of semiconductor manufacturing facilities. On the other hand, the transfer module 62 can be capable of omnidirectional movement, achieving a high degree of freedom in operating the wafer carriers 10. In some embodiments, each component, such as the linear actuator 62b, the lifter 62c, and the rotor 62d in the transfer module 62 can be independently controlled and finely tuned to accelerate or decelerate smoothly. This precise control can help prevent any positional shifts of the wafer containers during rapid movements or transitions, safeguarding the integrity of the wafers. In some embodiments, the transfer module 62 can include a robot.

The rack 100 can be equipped with multiple shelves 110 at different heights. Each shelf 110 can accommodate at least one wafer carrier 10, allowing the wafers in the wafer carriers 10 to be properly staged for the next processing step. The wafer carriers 10 can be positioned on the carrier support base 115 (see FIGS. 3 and 4). This setup can ensure that both wafer boats and carriers are securely positioned, ready for subsequent automated handling or processing stages. The length direction of shelf 110 in the rack 100 can extends along the horizontal slide rail 63b, creating a spatial relationship that can align with the movement path of wafer carriers 10, ensuring efficient transportation and positioning of wafer carriers 10 for various stages of semiconductor processing.

The carrier support base 115 can be arranged on the rack 100 in a matrix configuration. Specifically, the carrier support base 115 can be distributed across different positions on each shelf 110, allowing for versatile placement options and facilitates efficient use of the rack's capacity. By way of example and not limitation, along the length direction of the horizontal slide rail 63b, up to two can be installed side-by-side. Along the direction perpendicular to the horizontal slide rail 63b, there may be four carrier support bases 115 arranged. This matrix arrangement enables each shelf 110 to accommodate up to eight units, optimizing both space utilization and accessibility for automated wafer handling.

After the wafers complete the process in the production tool 3, the wafer container gripper 62a of transfer module 62 can grab the wafer carrier 10 from the production tool 3. Subsequently, the linear actuator 62b can move the wafer carrier 10 to the appropriate position while the lifter 62c assists in aligning wafer carrier 10 with the corresponding carrier support base 115 on the rack 100. Once aligned, the wafer container gripper 62a can place wafer carrier 10 onto the corresponding carrier support base 115. This sequence can ensure the precise handling and positioning of the wafer carrier 10, facilitating the smooth transition of the wafers between different stages of the semiconductor manufacturing process while minimizing the risk of misalignment or damage.

Reference is made to FIGS. 3 and 4. FIGS. 3 and 4 illustrate the positional relationship of the rack 100 in relation to the production tools 3, depicting the different positions before and after using the linear track system 200 to move the rack 100. In FIG. 3, the initial position of rack 100 can be shown, such as where it is actively being used in conjunction with production tools 3. This configuration can be scenarios where wafers need to be processed, stored, or staged, with the rack 100 positioned to support production activities. In some embodiments, as shown in FIG. 4, the rack 100 can be moved to a different position using the linear track system 200. This movement can allow the space initially occupied by rack 100 in FIG. 3 to be utilized for other purposes. For instance, the space could be used by automated robots for maneuvering, by other production equipment needing temporary access, or simply to allow for easier personnel movement in tight working environments. This repositioning not only can ensure space utilization but also provide flexibility in managing the layout of the semiconductor manufacturing facility.

Moreover, the rack 100 can be returned to its original position as shown in FIG. 3, allowing it to resume its role in production operations without the need for extensive recalibration. This ability to move back and forth between positions makes rack 100 highly versatile, when production processes require frequent reconfigurations. The fixing devices 250 and the linear track system 200 can ensure that each return can be accurate, thus minimizing production downtime and maintaining the precision necessary for semiconductor manufacturing.

In addition, there may be embodiments where, after being moved to the position shown in FIG. 4, the rack 100 can remain in this new position for subsequent stages of operation, which in turn allows for a dynamic production environment where the location of tools, materials, and storage must frequently adapt to changing needs. In some embodiments, the movement may be performed automatically, using such as a control system 60 (see FIG. 1) integrated with the linear track system 200 to determine the placement of the rack 100 based on the production schedule. In some embodiments, the ability to reposition the rack 100 precisely and efficiently also can reduce additional storage space. Instead of having multiple fixed racks throughout the facility, a few mobile racks with adjustable positioning can serve various roles, ranging from storage to temporary staging for different production steps, which in turn enhances the flexibility of the production environment, improves space utilization, and minimizes excess storage fixtures.

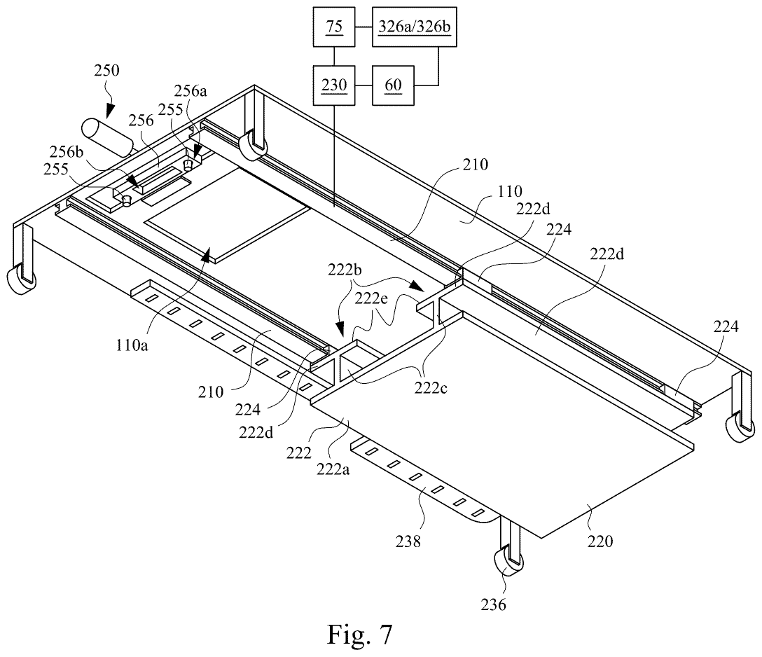

To move the rack 100 both accurately and quickly, reducing or eliminating lengthy calibration, the disclosure introduces the linear track system 200 to guide rack 100 precisely to its designated positions, as illustrated in FIGS. 3 and 4. By ensuring smooth and exact movement, the calibration time can be minimized, or even made unnecessary. Specifically, the linear track system 200 can include a movable rail 210 (see FIG. 7) and a positioning structure 220. In some embodiments, the movable rail 210 can be interchangeably referred to as a movable track.

Specifically, as shown in FIG. 7, the movable rail 210 can be installed at the bottom of shelf 110, which forms part of rack 100. The movable rail 210 can extend along the horizontal slide rail 63b (see FIGS. 3 and 4) of the transfer module 62, allowing the rack 100 to move smoothly along a well-defined path, guided by the rail system for accurate positioning. In some embodiments, the integration of the movable rail 210 with the horizontal slide rail 63b can enable coordinated movement across multiple racks 100 and production tools 3, thus supporting the overall efficiency of the automated production workflow.

The positioning structure 220 can enhance stability and control during the movement of the rack 100. As shown in FIG. 6, the positioning structure 220 can include a body portion 222 and sleeving portions 224. The body portion 222 can be fixed to the horizontal slide rail 63b (see FIGS. 3 and 4) of the transfer module 62 and extend towards the bottom of the rack 100. The body portion 222 can include a plate-shaped structure 222a and connecting structures 222b. The plate-shaped structure 222a can form the base of the positioning structure 220 and extends from the horizontal slide rail 63b, providing foundational support. The connecting structure 222b can be T-shaped, including a vertical portion 222c that extends upwards from the plate-shaped structure 222a, and two lateral portions 222d and 222e that extend horizontally from opposite sides of the vertical portion 222c. The connecting structure 222b can ensure a secure connection that maintains the alignment of the rack 100 during movement.

The sleeving portions 224 of the positioning structure 220 can be mounted on the lateral portions 222d of the connecting structures 222b. The sleeving portions 224 can be positioned such that they can correspond to the movable rail 210. The movable rail 210 can be movably inserted into the sleeving portions 224, creating a tight-fitting yet flexible joint that can allow the movable rail 210 to move freely while maintaining stability. When it comes to moving the rack 100, the linear track system 200 can operate with high precision. As the movable rail 210 moves relative to the sleeving portion 224, it drives the rack 100, allowing the rack 100 to move along the path defined by the horizontal slide rail 63b of the transfer module 62. The combination of these elements enables the rack 100 to move smoothly between different positions relative to the production tools 3.

Therefore, the positioning structure 220, with its T-shaped connecting elements and tight-fitting sleeving portions 224, can ensure that the rack 100 moves along a predetermined path without deviation. Since the rack 100 is moved along a well-defined, controlled path, calibration time can be reduced or even eliminated. The accuracy of the movement provided by the linear track system 200 can ensure that the rack 100 returns to its original position with high precision, making it unnecessary to perform lengthy recalibration processes.

In some embodiments, the movement of the movable rail 210 can be operated in either a manual or automatic mode. In manual mode, the movable rail 210 can be moved by an operator who physically adjusts the position of the rack 100 along the horizontal slide rail 63b. In automatic mode, the movement of the movable rail 210 can powered by a motorized actuator 230 (see FIG. 7), such as a linear actuator integrated with the movable rail 210. The automation can be controlled through a control system 60 that can be pre-programmed with specific movement instructions. Sensors along the track provide real-time feedback, allowing the control system (see FIG. 1) to monitor the rail's progress and adjust the speed or position.

In some embodiments, the linear track system 200 can be equipped with adjustable speed settings to optimize the movement of rack 100. A motion profile can include a three-phase speed control where the movement starts at a slow speed, transitions to a fast speed, and finally slows down again before coming to a stop. This slow-fast-slow speed profile can ensure both efficiency and precision. Specifically, the movement of the rack 100 can begin with a slow speed, allowing the linear track system 200 to gradually initiate the motion, avoiding any sudden jolts or vibrations that could disturb sensitive components, such as semiconductor wafers. The slow start can ensure that the rack 100 accelerates smoothly, giving time for the rack's position to be monitored and adjusted before the system increases speed. Once the rack 100 has cleared any sensitive areas and is securely on its track, the system can accelerate to a fast speed. During this phase, the rapid movement can increase the overall efficiency of the system by reducing transit time. As the rack 100 approaches its destination, the system can gradually reduce the speed back to slow. This deceleration phase can ensure that the rack 100 can be precisely aligned with its target position without overshooting or causing any mechanical stress. The final slow approach can allow the system to make fine adjustments.

After the rack 100 is moved to the predetermined position, the rack 100 can be secured in place to maintain stability and ensure accurate alignment for subsequent operations through the fixing device 250, which can effectively lock the rack 100 into its designated position. The fixing device 250 may be installed on the lowermost shelf 110 of the rack 100, offering both security and ease of operation. In some embodiments, the fixing device 250 may also be referred to as a quick-clamp device. As shown in FIGS. 6-8C, the fixing device 250 can include several components that work in conjunction to stabilize the rack 100: a fixing component 251, moving components 252 and 253, a rotating component 254, an insertion component 255, and a positioning component 256. In some embodiments, the rotating component 254 can be interchangeably referred to as a rotational actuator.

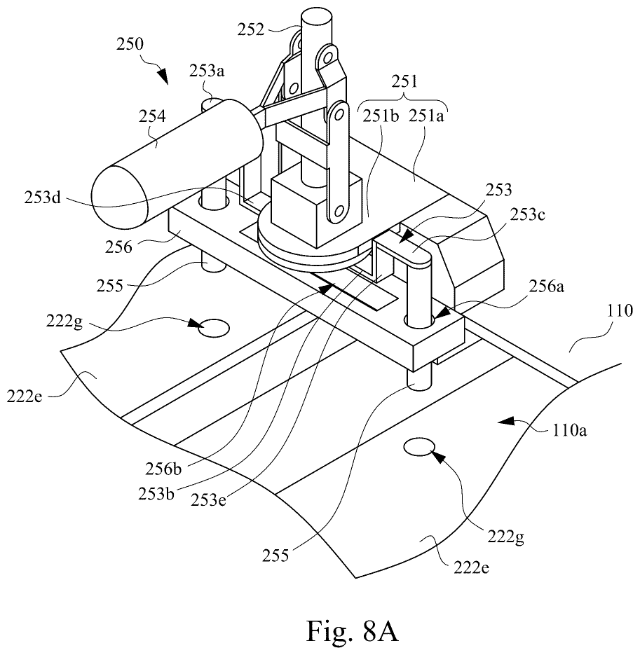

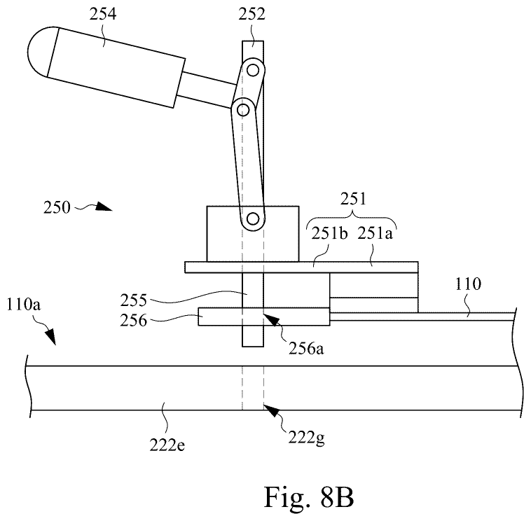

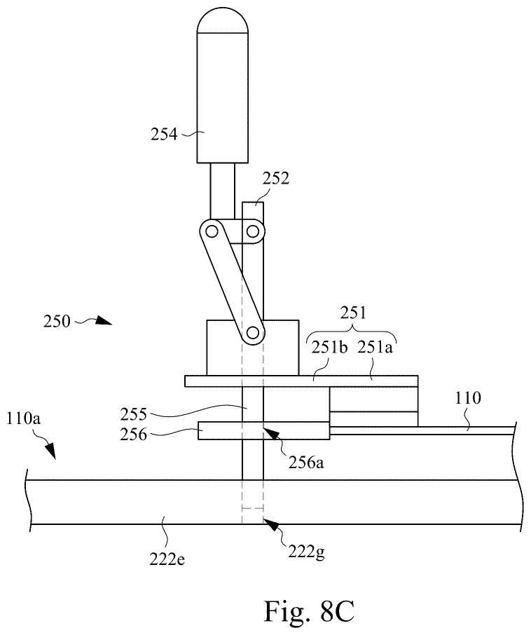

As shown FIGS. 8A-8C, the fixing component 251 can serve as the foundation of the fixing device 250, providing a stable attachment point for the entire mechanism. Specifically, the fixing component 251 can be fixed to the shelf 110, which is designed with an opening 110a. The fixing component 251 can include a fixing body 251a and a fixing plate 251b. The fixing body 251a can be securely attached to the top surface of the shelf 110 and positioned at the edge of the opening 110a, acting as the anchor for the fixing device 250 and ensuring that all components can remain firmly in place. The fixing plate 251b can extend horizontally from the fixing body 251a. The fixing plate 251b can extend above the opening 110a, serves as a guide and support for the moving components and ensuring consistent positioning and alignment during movement.

In FIGS. 8A-8C, the moving component 252 can be a rod-like structure that can serve as an intermediary element connecting the rotating component 254 and moving component 253. The moving component 252 can pass through the fixing plate 251b of the fixing component 251, allowing it to pivot and transmit force effectively. The moving component 252 can transfer the rotational force generated by the rotating component 254 to the rest of the fixing mechanism.

Additionally, the moving component 253 can be designed to guide the movement of the insertion component 255, enabling precise positioning of rack 100. The moving component 253 can be a plate-like structure and can be connected to the end of the moving component 252 opposite the rotating component 254. The moving component 253 can be positioned between the moving component 252 and the insertion component 255, ensuring that the force exerted by the rotating component can be accurately translated into vertical movement. In some embodiments, the moving component 253 can be configured with a multi-bend structure and include three horizontal sections 253a, 253b, 253c and two vertical sections 253d, 253e. The vertical section 253d can connect the horizontal sections 253a and 253b, and the vertical section 253e can connect the horizontal sections 253b and 253c. The horizontal section 253b can be positioned between horizontal sections 253a and 253c and can be configured to be pushed by the moving component 252. The horizontal sections 253a and 253c can be each fitted with an insertion component 255, which can be a rod-like structure extending downward. The insertion components 255 can be responsible for engaging with the positioning structure to secure the rack.

The insertion component 255 can be used for anchoring the rack 100 in place. It is a rod-like structure that can extend downward from the horizontal sections 253a and 253c of the moving component 253. When the fixing device 250 is engaged, the insertion component 255 moves into a designated positioning hole, thereby locking the rack 100 into position. The insertion component 255 can ensures that the rack 100 can be fixed securely, minimizing any movement or vibration that could affect subsequent operations.

The positioning component 256 can be fixed to the shelf 110 and extend within the opening 110a. The positioning component 256 can have guide openings 256a and a receiving opening 256b. The guide openings 256a can be used to direct the insertion component 255 during vertical movement, ensuring that it moves along the correct path. The receiving opening 256b can be used to accommodate the moving component 253 as it moves downward, preventing any obstruction from the positioning component 256 during operation. The positioning component 256 can ensure that all moving parts can be precisely guided and that the insertion component 255 can effectively engage with the designated locking point. In some embodiments, the guide openings 256a can be interchangeably referred to as an alignment feature.

As shown in FIG. 8C, once rack 100 is moved to its predetermined position, it must be stabilized to ensure that it remains securely in place during subsequent operations. To achieve this, the rotating component 254 of the fixing device 250 can be engaged. By rotating the rotating component 254, force is applied to both moving component 253 and moving component 252. This force can be transmitted through the moving components 252 and 253, causing the insertion component 255 to move downward. As the insertion component 255 moves downward, it can align with positioning holes 222g located in the lateral portions 222e of the connecting structure 222b of the positioning structure 220. The insertion component 255 can continue to move downward until it is fully inserted into the positioning holes 222g, thereby locking rack 100 into the positioning structure 220, ensuring that the rack 100 can be securely fixed in place, preventing any unintended movement or misalignment.

In some embodiments, the fixing device 250 can be a manual quick-clamp device. In some embodiments, the fixing device 250 can be an automatic quick-clamp system, such that the fixing device 250 can be controlled electronically, allowing for faster and more consistent engagement and release of the clamps.

In some embodiments, the rack 100 can be equipped with tires 236 or other elements designed to facilitate its movement along the linear track system 200, ensuring the smooth and efficient transportation of the rack 100 between different positions within the semiconductor manufacturing facility. Specifically, the tires 236 may be positioned at the base of the rack 100. The tires 236 can be made from durable materials, such as rubber or polyurethane, that can offer excellent wear resistance and can support the weight of the rack and its contents, such as wafer carriers. The tires 236 can enable the rack 100 to move easily along the linear track system 200, reducing friction and minimizing the physical effort required to reposition the rack. In some embodiments, the tires 236 can be fixed tires that can provide stable, linear movement, enabling that the rack 100 moves along a straight path. In some embodiments, the tires 236 can be swivel tires that can provide multi-directional movement, enabling the rack 100 to turn and maneuver in tight spaces. In some embodiments, the tires 236 can be replaced with sliding pads or ball bearings.

In some embodiments, the linear track system 200 can include a visual and audible Indicator. Specifically, the process of engaging or releasing the fixing device 250 could be accompanied by the visual indicator 240 (e.g., screen, LED lights) and audible alerts (not shown) to notify operators that the rack 100 has been secured or released, enhancing the safety of the operation and ensuring that personnel are aware of the rack's status at all times. During the movement, the linear track system 200 could also log diagnostic data, such as movement duration, locking (e.g., clamp engagement) status, and sensor data, into the archive data base 75 (see FIG. 1). This information could be analyzed to improve the movement process, identify bottlenecks, and enhance overall efficiency, and this information can be displayed on the visual indicator 240. For example, the visual indicator 240 can be activated to visually signal when the fixing device 250 is engaged or released.

As shown in FIG. 7, a cable management system can include a cable drag chain 238 installed on the bottom surface of the shelf 110, located at the base of the rack 100. This cable drag chain 238 can be designed to manage and protect cables during the movement of the rack 100, ensuring that they remain untangled and securely in place as the rack 100 shifts along its path. The cable drag chain 238 can be positioned next to the movable rail 210, extending along the same length as the movable rail 210. This parallel configuration can ensure that the cable drag chain 238 moves in synchrony with the movable rail 210, effectively guiding and securing the cables during the rack's transit. In some embodiments, the cable drag chain 238 can be installed in such a way that the bottom of the cable drag chain 238 is positioned higher than the bottom of the positioning structure 220. In some embodiments, by positioning the cable drag chain 238 at a higher level, the linear track system 200 can minimize the risk of interference or entanglement between the cables and the positioning structure 220, ensuring smooth and unhindered movement of both the rack and the cables.

In some embodiments, a position detection system 326, integrated into the transfer module 62, which can enhance the precision and stability of rack movements during semiconductor manufacturing processes. The position detection system 326 can be equipped with positioning sensors 326a and 326b that monitor the rack's position in both horizontal and vertical axes, ensuring proper alignment and reducing operational risks.

As shown in FIGS. 3-5, the positioning sensors 326a can be installed along the horizontal slide rail 63b of the transfer module 62. By being positioned along the length of the slide rail, the positioning sensor 326a can continuously track the horizontal movement of the rack 100, verifying that it remains on its intended path throughout transit, which in turn allows for being capable of checking the rack's position at set intervals, such as during motion and upon reaching a stop. This real-time monitoring can ensures the rack's accurate alignment with the production tools 3 and minimizes misalignment risks.

The positioning sensor 326b can be installed on the lifter 62c of the transfer module 62. The sensor 326b can provide feedback on the vertical positioning of the rack 100. In some embodiments, the positioning sensor 326b may be placed on both the top and bottom portions of the lifter 62c. By being attached to the lifter 62c, the positioning sensor 326b can move with the rack 100 along the horizontal slide rail 63b, providing constant updates on the height and confirming the correct positioning for different stages of processing. In some embodiments, the positioning sensors 326a and 326b can operate together, continuously gathering data on the position, alignment, and stability of the rack 100 during various stages of movement.

When an abnormal condition, such as a deviation from the intended path, incorrect elevation, or misalignment, is detected, the positioning sensors 326a and 326b can send an immediate signal to the control system 60 (see FIG. 1), enabling the system to respond by either correcting the error or halting further movement until the issue is addressed, ensuring that any potential issues are managed proactively. In some embodiments, the control system 60 can trigger an emergency stop. This may halt all movements of the rack 100, lifter 62c, and horizontal slide rail 63b, preventing any potential collisions or further misalignment. This function is essential to protect both the machinery and the wafers from potential damage. In some embodiments, the positioning sensors 326a and 326b can be proximity sensors. In some embodiments, the position detection system 326 may also be equipped with vibration sensors to detect any unexpected movements or vibrations during rack transit.

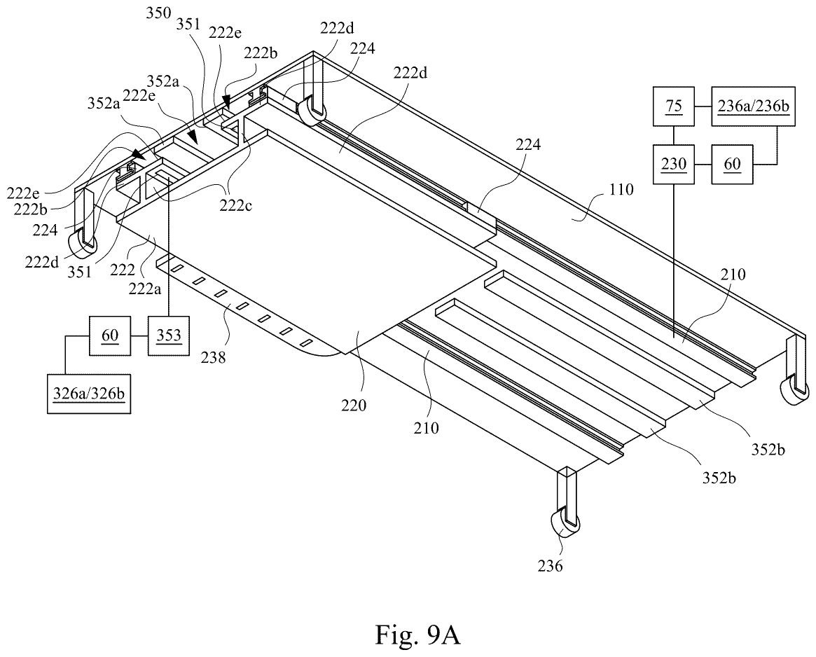

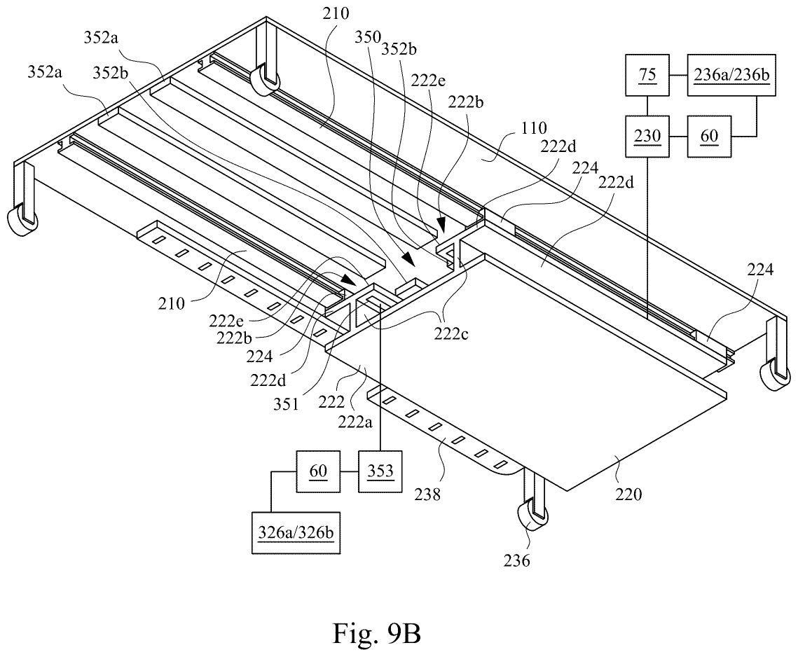

Reference is made to FIGS. 9A and 9B. FIGS. 9A and 9B illustrate schematic views of various stages of a method for moving the rack 100 by a linear track system 200 in accordance with some embodiments of the present disclosure. In some embodiments, an electromagnetic brake system 350 could be used as an alternative to the fixing device 250. In some embodiments, the electromagnetic brake system 350 can include electromagnetic coil 351, brake plates 352a and 352b, a power supply unit 353, the control system 60 (see FIG. 1), and positioning sensors 326a (see FIGS. 3-5).

As shown in FIGS. 9A and 9B, the electromagnetic coil 351 that generate the magnetic force can hold the rack 100 in place. In some embodiments, the electromagnetic coil 351 can be installed (or mounted) on the positioning structure 220, near where the rack 100 comes to rest. When an electric current flows through the electromagnetic coil 351, the electromagnetic coils 351 can create a magnetic field that generates the holding force. The brake plates 352a and 352b can be attached to the rack 100. The brake plates 352a and 352b can be aligned with the electromagnetic coil 351, respectively, and serves as the surface to which the magnetic field adheres. The brake plate can be made of a ferromagnetic material that is compatible with the electromagnetic coil 351 to ensure a secure hold. When the electromagnetic coil 351 is energized, the brake plate 352/352b can be attracted to it, effectively securing the rack 100. The power supply unit 353 can energize the electromagnetic coil 351. The control system 60 can determine when to activate or deactivate the electromagnetic brake system 350, ensuring that the braking mechanism can be engaged when the rack 100 needs to be moved. The positioning sensors 326a (see FIGS. 3-5) can be used to detect when the rack 100 has reached its predetermined position. The positioning sensors 326a can send signals to the control system 60 to trigger the electromagnetic brake, ensuring precise timing for locking the rack in place.

As the rack 100 moves along its designated path, the positioning sensors 326a can detect when it has arrived at the target location. Once this position is confirmed, the control system 60 can send a signal to energize the electromagnetic coil 351. Once energized, the electromagnetic coil 351 can generate a magnetic field that pulls the brake plate 352a or 352b towards it. The strong magnetic force securely holds the rack 100 in place, preventing any unintended movement. The mechanism of the electromagnetic brake system 350 can act similarly to the fixing device 250 by ensuring that the rack 100 remains locked in a stable position. When the rack 100 needs to be moved again, the control system 60 can deactivate the electromagnetic coil 351 by cutting off the power supply, disengaging the magnetic field, which in turn allows the rack 100 to be freely moved along the track to its next position. In some embodiments, the electromagnetic brake system 350 can have no physical contact parts that slide or rub against each other during normal operation, thereby reducing mechanical wear and tear.

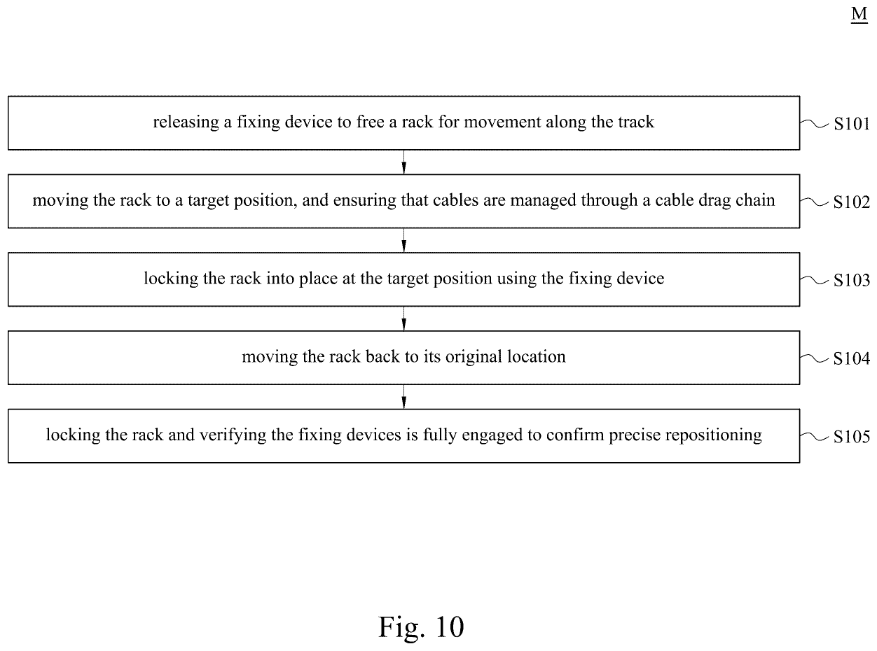

Reference is made to FIG. 10, which illustrates a flowchart of a method for using a linear track system 200 to the move rack 100 as illustrated in FIGS. 3-9B in accordance with some embodiments of the present disclosure. The described method M outlines steps for the movement process. It is to be understood that additional operations may be performed before, during, or after the steps shown in FIGS. 3-9B, and that some of the described steps may be replaced or omitted in other embodiments. Furthermore, the order of these operations or processes may be interchangeable, providing flexibility depending on specific requirements.

The method M begins at block S101 where releasing the fixing device 250 (e.g., quick-clamp device) to free the rack 100 for movement along the track (e.g., positioning structure 220). Specifically, the process begins by releasing the fixing device 250 securing the rack 100 in its current position. The fixing device 250 can ensure that the rack 100 remains stable during periods of inactivity, and by releasing them, the rack 100 becomes free to move.

The method M then proceeds to block S102 where moving the rack 100 to the a target position, and ensuring that cables are managed through the cable drag chain. Specifically, once the fixing device 250 is released, the rack 100 can be moved along the track of the linear track system 200, allowing it to slide horizontally to the desired position. During this movement, cable management can be handled by the cable drag chain 238 that keeps all cables organized, preventing tangling and ensuring the smooth and safe movement of the rack 100. The cable drag chain 238 can extends alongside the rack 100 and the movable rail 210 of the linear track system 200, ensuring that power and data cables are not overstretched or damaged during transit.

The method M then proceeds to block S103 where locking the rack 100 into place at the target position using the fixing device 250, ensuring stability. After the rack 100 reaches the desired location, the fixing device 250 can be engaged again to secure the rack 100 in place. By locking (e.g., rotating, pressing, actuating) the fixing device 250, the fixing device 250 (e.g., clamp) can lock onto the track, ensuring that the rack remains fixed at the intended position, which in turn allows for maintaining the rack's stability and precision alignment within the production area. A verification process follows, ensuring that the fixing devices 250 is fully engaged, which may guarantee that the rack 100 has been accurately positioned. The fixing device 250 not only can lock the rack 100 into position but also acts as a stabilizing element, reducing vibrations that might affect any ongoing operations, and ensuring that the semiconductor wafers stored or processed in the rack are kept in an environment without disturbance.

The method M then proceeds to block S104 where when needed, moving the rack back to its original location. Specifically, when needed, the rack 100 can be moved back to its original position. This can be achieved by once again releasing the fixing device 250, allowing the rack 100 to slide along the track in the reverse direction.

The rack 100 can be returned to its original position using the linear track system 200, and as in the initial movement, the cable drag chain 238 can ensure that all cables remain organized, untangled, and protected from damage. This step can allow the rack 100 to be repositioned quickly and accurately, eliminating the need for extensive recalibration and minimizing downtime in the production line.

The method M then proceeds to block S105 where locking the rack 100 and verifying all fixing devices 250 are fully engaged to confirm precise repositioning. Specifically, after the rack 100 reaches its original or intended position, the fixing device 250 can be engaged again to lock it in place. This step can include rotating (e.g., pressing, actuating) the fixing device 250 to confirm that (e.g., all three clamps) are properly locked and that rack 100 is secure. A verification process follows, ensuring that the fixing devices 250 is fully engaged, which may guarantee that the rack 100 has been accurately repositioned. At this stage, the precise alignment of the rack 100 can be confirmed, making sure that it has returned to its original configuration without any deviation.

In some embodiments, throughout the movement process, positioning sensors 326a and 326b (see FIGS. 3-5) can be integrated into the linear track system 200. The positioning sensors 326a and 326b can monitor the rack's progress and ensure it is on the correct path. The positioning sensors 326a and 326b can provide real-time feedback to the control system 60.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a mechanical structure that can allow the rack to be moved along a track and return precisely to their original position. This mechanical structure that can include a fixing device (e.g., manual quick-clamp device) and a linear track system. The fixing device can fix the rack securely in place both before and after movement, ensuring that the rack remains stable and is accurately repositioned. The rack can be mounted on a track that facilitates smooth horizontal movement. This disclosure also can incorporate a cable drag chain to manage cables during movement, reducing the risk of tangling and ensuring safe, orderly operation. Therefore, this disclosure can allow for movement of the rack, with the fixing device being released to allow for movement along the track. After reaching the desired position, the fixing device can be re-engaged to secure the rack in its desired position without the need for extensive recalibration.

In some embodiments, a method includes releasing a fixing device to allow a movement of a rack using a movable track of a linear track system at a first position; moving the rack using the movable track from the first position to a second position; engaging the fixing device to secure the rack in place at the second position; releasing the fixing device to allow the rack to return to the first position using the movable track; engaging the fixing device to lock the rack at the first position. In some embodiments, the rack is configured to accommodate wafer carriers that are loaded and unloaded using a transfer module for transporting semiconductor wafers. In some embodiments, the movement of the rack is performed by suing the movable track of the linear track system mounted on a lowermost shelf of the rack. In some embodiments, the movable track is operatively associated with a positioning structure installed on a horizontal slide rail of a transfer module. In some embodiments, the method further includes adjusting a speed of the movement of the rack to minimize vibrations of the rack. In some embodiments, the fixing device is secured at a lowermost shelf of the rack. In some embodiments, the fixing device is a quick-clamp device. In some embodiments, the linear track system further comprises a cable drag chain configured to manage a movement of cables connected to the rack during the movement of the rack along the movable track. In some embodiments, the cable drag chain is positioned along the movable track. In some embodiments, the method further includes activating an indicator to visually signal when the fixing device is engaged or released.

In some embodiments, disengaging a securing mechanism to initiate a movement of a wafer carrier rack using a movable track of a linear guidance system from an initial position, wherein the linear guidance system is configured on a lowermost shelf of the wafer carrier rack; advancing the wafer carrier rack using the movable track to a target position; applying the securing mechanism to secure the wafer carrier rack at the target position; utilizing a cable drag chain, positioned parallel to the movable track, to guide cables during the movement of the wafer carrier rack. In some embodiments, the method further includes releasing the securing mechanism to enable the wafer carrier rack to return from the target position to the initial position using the movable track; locking the securing mechanism to ensure the wafer carrier rack remains in place at the initial position. In some embodiments, the method further includes detecting an alignment of the wafer carrier rack at the initial and target positions using a position detection system. In some embodiments, the method further includes using a transfer module to facilitate the movement of the wafer carrier rack, wherein the transfer module is configured to handle wafer carriers for loading and unloading operations. In some embodiments, the transfer module comprises a horizontal slide rail for guiding the movement of the wafer carrier rack, wherein the horizontal slide rail is operatively coupled to the linear guidance system.

In some embodiments, a system includes a rack, a horizontal rail, a linear guidance system, and a securing mechanism. The rack having multiple shelves is configured to accommodate wafer carriers used in semiconductor processing. The horizontal rail is positioned adjacent to the rack. The linear guidance system is disposed below the rack. The linear guidance system includes a movable track integrated with the rack, configured to enable a horizontal movement of the rack along a predefined path, and a positioning assembly mechanically coupled to the horizontal rail and operatively engaging with the movable track. The securing mechanism is attached to the rack. The securing mechanism is operable to lock the rack in position. The securing mechanism includes a rotational actuator configured to drive an insertion element into an alignment feature within the positioning assembly. In some embodiments, the linear guidance system further comprises a cable drag chain positioned below the rack, and the cable drag chain is configured to manage and protect cables during the horizontal movement. In some embodiments, the securing mechanism comprises a quick-clamp device operable to lock and unlock the rack in a repeatable manner. In some embodiments, the securing mechanism further comprises a positioning component mechanically coupled to one of the shelf of the rack, and the positioning component is configured to guide the insertion element of the securing mechanism aligns with the alignment feature within the positioning assembly. In some embodiments, the positioning assembly further comprises a locking indicator mounted on the rack, the locking indicator is operative to provide a signal when the rack is securely locked in position.

In some embodiments, a system includes a transfer module, a movable rack, a linear track system, and a securing mechanism. The transfer module is configured to transfer a wafer carrier. The movable rack is positioned adjacent to the transfer module, wherein the movable rack is configured to accommodate the wafer carrier and is operable to move between a first position and a second position. The linear track system includes a track and a positioning structure. The track is mounted on a lowermost shelf of the movable rack and is configured to enable a horizontal movement of the movable rack along a defined path. The positioning structure is coupled to a rail of the transfer module, wherein the positioning structure is configured to guide the movable rack during the horizontal movement using the track and to ensure an alignment of the movable rack at the first and second positions. The securing mechanism is mounted on the movable rack, wherein the securing mechanism is configured to selectively engage and disengage to secure the movable rack in place at either the first or second position. In some embodiments, the securing mechanism comprises a rotational actuator configured to drive an insertion component, wherein the insertion component extends into an alignment feature of the positioning structure to mechanically lock the movable rack in the first or second position. In some embodiments, the securing mechanism is integrated into the lowermost shelf of the movable rack. In some embodiments, a system further includes a cable management system, and the cable management system includes a cable drag chain mounted alongside the track of the linear track system. In some embodiments, a system further includes a positioning sensor assembly, and the positioning sensor assembly is integrated within the transfer module, wherein the positioning sensor assembly comprises one or more sensors configured to continuously monitor and provide real-time feedback regarding the alignment of the movable rack at the first and second positions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
releasing a fixing device to allow a movement of a rack using a movable track of a linear track system at a first position;
moving the rack using the movable track from the first position to a second position;
engaging the fixing device to secure the rack in place at the second position;
releasing the fixing device to allow the rack to return to the first position using the movable track; and
engaging the fixing device to lock the rack at the first position.

2. The method of claim 1, wherein the rack is configured to accommodate wafer carriers that are loaded and unloaded using a transfer module for transporting semiconductor wafers.

3. The method of claim 1, wherein the movement of the rack is performed by suing the movable track of the linear track system mounted on a lowermost shelf of the rack.

4. The method of claim 3, wherein the movable track is operatively associated with a positioning structure installed on a horizontal slide rail of a transfer module.

5. The method of claim 1, further comprising:
adjusting a speed of the movement of the rack to minimize vibrations of the rack.

6. The method of claim 1, wherein the fixing device is secured at a lowermost shelf of the rack.

7. The method of claim 1, wherein the fixing device is a quick-clamp device.

8. The method of claim 1, wherein the linear track system further comprises a cable drag chain configured to manage a movement of cables connected to the rack during the movement of the rack along the movable track.

9. The method of claim 8, wherein the cable drag chain is positioned along the movable track.

10. The method of claim 1, further comprising:
activating an indicator to visually signal when the fixing device is engaged or released.

11. A system, comprising:
a rack having multiple shelves configured to accommodate wafer carriers used in semiconductor processing;
a horizontal rail positioned adjacent to the rack;
a linear guidance system disposed below the rack, comprising:
a movable track integrated with the rack, configured to enable a horizontal movement of the rack along a predefined path; and
a positioning assembly mechanically coupled to the horizontal rail and operatively engaging with the movable track; and
a securing mechanism attached to the rack, operable to lock the rack in position, the securing mechanism comprising a rotational actuator configured to drive an insertion element into an alignment feature within the positioning assembly.

12. The system of claim 11, wherein the linear guidance system further comprises a cable drag chain positioned below the rack, and the cable drag chain is configured to manage and protect cables during the horizontal movement.

13. The system of claim 11, wherein the securing mechanism comprises a quick-clamp device operable to lock and unlock the rack in a repeatable manner.

14. The system of claim 11, wherein the securing mechanism further comprises a positioning component mechanically coupled to one of the shelf of the rack, and the positioning component is configured to guide the insertion element of the securing mechanism aligns with the alignment feature within the positioning assembly.

15. The system of claim 11, wherein the positioning assembly further comprises a locking indicator mounted on the rack, the locking indicator is operative to provide a signal when the rack is securely locked in position.

16. A system, comprising:
a transfer module configured to transfer a wafer carrier;
a movable rack positioned adjacent to the transfer module, wherein the movable rack is configured to accommodate the wafer carrier and is operable to move between a first position and a second position;
a linear track system comprising:
a track mounted on a lowermost shelf of the movable rack, configured to enable a horizontal movement of the movable rack along a defined path; and
a positioning structure coupled to a rail of the transfer module, wherein the positioning structure is configured to guide the movable rack during the horizontal movement using the track and to ensure an alignment of the movable rack at the first and second positions; and
a securing mechanism mounted on the movable rack, wherein the securing mechanism is configured to selectively engage and disengage to secure the movable rack in place at either the first or second position.

17. The system of claim 16, wherein the securing mechanism comprises a rotational actuator configured to drive an insertion component, wherein the insertion component extends into an alignment feature of the positioning structure to mechanically lock the movable rack in the first or second position.

18. The system of claim 16, wherein the securing mechanism is integrated into the lowermost shelf of the movable rack.

19. The system of claim 16, further comprising:
a cable management system comprising a cable drag chain mounted alongside the track of the linear track system.

20. The system of claim 16, further comprising:
a positioning sensor assembly integrated within the transfer module, wherein the positioning sensor assembly comprises one or more sensors configured to continuously monitor and provide real-time feedback regarding the alignment of the movable rack at the first and second positions.
